(19) United States
(12) Patent Application Publication
(10) Pub. No.: US 2010/0044098 A1
(43) Pub. Date: Feb. 25, 2010

(54) Electrical Conductive Structure and Electrical Device

(75) Inventors: Zolas Liao, Dong-Guan City (CN); LF Liang, Dong-Guan City (CN)

Correspondence Address: GROSSMAN, TUCKER, PERREAULT & PFLEGER, PLLC, 55 SOUTH COMMERICAL STREET, MANCHESTER, NH, 03101, US

(73) Assignee: Delta Electronics, Inc., Taoyuan Hsien (TW)

(21) Appl. No.: 12/269,258

(22) Filed: Nov. 12, 2008

(30) Foreign Application Priority Data
Aug. 19, 2008 (TW) 097214849

(51) Int. Cl. H01B 5/00; H05K 9/00

(52) U.S. Cl. 174/350; 174/126.1; 361/818

(57) ABSTRACT

An electrical conductive structure and an electrical device comprising the electrical conductive structure are provided. The electrical conductive structure comprises a copper foil and at least one wire. The wire is disposed on the surface of the copper foil by spot welding. The electrical conductive structure is adapted to be the primary winding and/or the secondary winding of an inductive component within an electrical device as well as an electromagnetic interference (EMI) shielding between each of the winding. The electrical conductive structure of this invention combines the copper foil and at least one wire by spot welding to decrease the volume of the electrical device and to lower the costs of the assembly process.

This application claims priority to Taiwan Patent Application No. 097214849 filed on Aug. 19, 2008, the disclosure of which is incorporated herein by reference in its entirety.

### CROSS-REFERENCES TO RELATED APPLICATIONS

Not applicable.

### BACKGROUND OF THE INVENTION

1. Field of the Invention

The present invention provides an electrical conductive structure for use in electrical devices such as inductive components.

2. Descriptions of the Related Art

Various electrical devices that are currently available are equipped with electromagnetic inductive components that convert electric energy into magnetic energy or vice versa for filtering, energy storage or energy discharge purposes. These components help stabilize the output current. Such electromagnetic inductive components generally incorporate an electrical conductive structure which basically has two functions: to serve as a primary winding and/or a secondary winding of the electromagnetic inductive component directly, and to serve as a shielding layer between the primary winding and the secondary winding or between the individual electrical components of the electronic device to mitigate electromagnetic interference (EMI) and prevent adverse influences on the human body and electrical devices from the electromagnetic waves.

FIG. 1 depicts a conventional electrical conductive structure 1, which comprises a copper foil 11 and a wire 13. The wire 13 is disposed on the surface of the copper foil 11 as a pin to electrically connect the electrical conductive structure 1 with an electrical device. The wire 13 is typically soldered to the copper foil 11. A solder ball 15 is formed at a location where the copper foil 11 and the wire 13 are connected. However, an oversized solder ball 15 increases volume and occupies more space in the electrical conductive structure 1 and consequently increases the size of the electrical device as a whole, which is in contradiction to the current tendency towards lightweight, thin and miniaturized electrical devices. Furthermore, using soldering tin incurs additional cost of materials and the manufacturing process, which has a negative impact on competitiveness in price of the product.

As seen from the above description, the electrical conductive structures currently available mostly have wire that is soldered onto copper foil. However, this practice will cause increased volume and higher costs. Therefore, efforts still have to be made in the art to provide a smaller electrical conductive structure at lower manufacturing costs.

### SUMMARY OF THE INVENTION

This invention provides a novel electrical conductive structure which, with smaller space occupation, can serve as a primary winding and/or secondary winding of an inductive component in an electrical device or as a shielding layer for obviating the EMI between individual windings.

The electrical conductive layer of this invention comprises a copper foil and at least one wire spot-welded on the copper foil. Unlike the conventional connection accomplished by soldering, this invention can prevent the formation of an oversized solder ball where the copper foil contacts at least one wire, thus effectively reducing the volume of the electrical conductive structure. Meanwhile, spot-welding the copper foil and at least one wire may further simplify the manufacturing procedures and reduce the costs of the material and assembly process, which helps to strengthen market competitiveness of the final product.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a schematic view of a conventional electrical conductive structure;

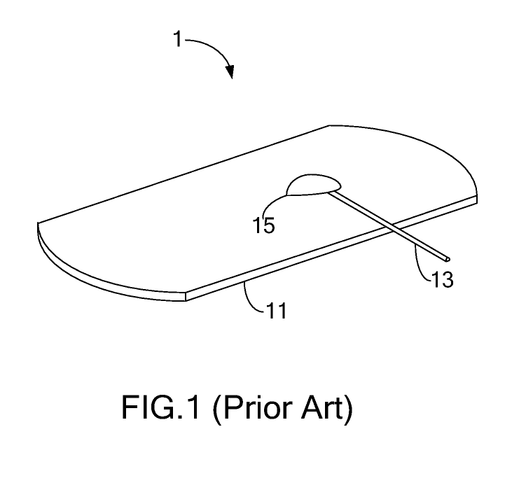

FIG. 2 is a schematic view of an electrical conductive structure of this invention;

FIG. 3A is a schematic view of an electrical structure of this invention; and

FIG. 3B is a schematic view of another electrical conductive structure used in FIG. 3A.

### DESCRIPTION OF THE PREFERRED EMBODIMENT

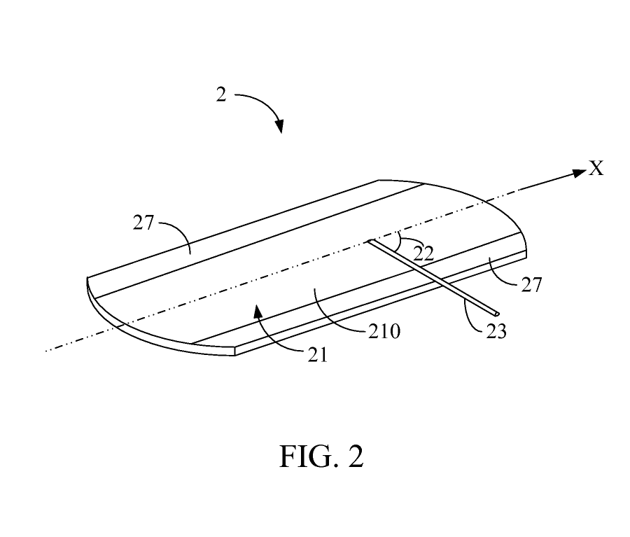

FIG. 2 depicts an embodiment of this invention, which is an electrical conductive structure 2. The electrical conductive structure 2 comprises a copper foil 21, a wire 23 and an insulating layer 27. The copper foil 21 has a first surface 210 and a second surface (not shown) opposite the first surface 210. The wire 23 is disposed adjacent to the first surface 210, while the insulating layer 27 is disposed adjacent to the second surface and folded back to cover an upper and lower portion of the first surface 210.

More specifically, the wire 23 is spot-welded on the first surface 210 of the copper foil 21 so that the copper foil 21 and the wire 23 are substantially connected with each other. The wire 23 is made of copper, e.g., enameled copper wire. However, in other embodiments, the wire 23 may also be made of other materials. It should be noticed that in other embodiments, the number of wires included in the electrical conductive structure is not limited. Also, the wire(s) and the copper foil may be substantially connected with each other by a high temperature or high pressure melt. Furthermore, this connection may also be accomplished by melting only either the copper foil 21 or the wire 23. Thus, the connection can be made with other methods not limited to what described in this embodiment.

The copper foil 21 has a longitudinal direction X. After the wire 23 and the copper foil 21 are connected with each other, an extension line of the wire 23 forms an included angle 22 of less than 180° with the longitudinal direction X of the copper foil 21. Because the wire 23 is subject to bending, it may also be arranged on the copper foil 21 in parallel with the longitudinal direction X in other embodiments. The way in which the copper foil 21 and the wire 23 are arranged is not limited to what is described in this embodiment. Rather, in practical applications, the wire 23 may be connected to the copper foil 21 at other relative positions or angles.

In this embodiment, the insulating layer 27 is combined with the second surface and portions of the first surface of the copper foil 21 to define an exposed area on the first surface 210 of the copper foil 21 for the wire 23 being spot-welded thereon. In this embodiment, this is accomplished by adhesion. However, in other embodiments, this may also be accomplished by any other conceivable means. In this embodiment, the insulating layer 27 is an insulation tape. However, the insulating layer 27 is not limited to this material. Also, the location of the insulating layer 27 on the electrical conductive structure 2 is not limited to what is described herein, and those skilled in the art may determine the location of the insulating layer 27 on the electrical conductive structure 2 according to practical conditions. Because the insulating layer 27 electrically isolates the copper foil 21 and the wire 23 of the electrical conductive structure 2 from adjacent electrical components, short-circuits arising from the contact of the copper foil 21 and wire 23 with adjacent electrical components are prevented.

In this embodiment, the wire 23 and the copper foil 21 are joined together with spot-welding to form a pin, so that the electrical conductive structure 2 can be electrically connected to other electrical components or circuit boards. Forming the electrical conductive structure 2 through spot-welding may prevent the formation of an oversized solder ball at the connecting point that would normally occur if conventional soldering were used to connect the wire 23 and the copper foil 21. As a result, this may decrease the volume of the electrical conductive structure 2, and reduce costs of the assembly materials by obviating the need of soldering tin.

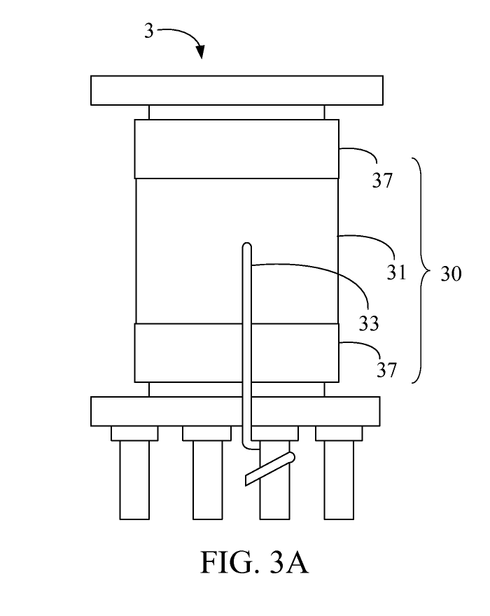

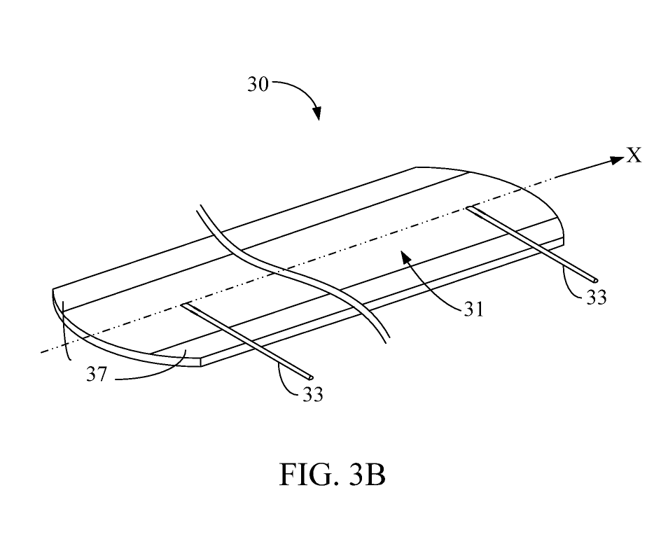

This invention further provides an electrical device 3, a structure of which is partially depicted in FIG. 3A. The electrical device may be an inductive component which, in this embodiment, is a transformer for transforming a voltage received from a voltage input (not shown) into a different voltage level to be outputted via a voltage output (not shown).

The electrical device 3 comprises electrical conductive structures 30, a schematic view of which is shown in FIG. 3B. Each of the electrical conductive structures 30 comprises a copper foil 31, two wires 33 and an insulating layer 37. Similar to what is described above, the wires 33 are spot-welded on the copper foil 31. However, unlike the above embodiment where the wire 23 is disposed at one end of the copper foil 21, the two wires 33 are disposed at both ends of the copper foil 31 respectively herein. One of the electrical conductive structures 30 has wires 33 at both ends thereof connected to the voltage input to function as a primary winding, while the other electrical conductive structure 30 has wires 33 at both ends thereof connected to the voltage output to function as a secondary winding. The two electrical conductive structures 30 used as the primary winding and the secondary winding respectively have copper foils 31 of different lengths corresponding to different winding numbers to induce different voltage levels. It should be noticed that, examples in which only one of the primary winding and the secondary winding adopts the electrical conductive structure of this invention and the other adopts a coil winding may also occur to those skilled in the art.

In other examples, the electrical conductive structure 30 may also be disposed between the primary winding and the secondary winding, with the wire 33 disposed on the copper foil 31 connected to the ground terminal of the electrical device 3 to provide a grounding effect. In this way, the electrical conductive structure 30 forms a shielding layer capable of mitigating the EMI. There may be either a single or a plurality of wires 33 disposed on the copper foil 31, and in the case of a plurality of wires 33, the other end of each wire 33 should also be grounded. In this embodiment, there is only a single wire 33 as shown in FIG. 3A. It should be noted that in this case, an insulating layer should also be attached at appropriate locations depending on the practical applications to prevent short-circuiting of the wire(s) disposed on the copper foil. This can obviate the EMI that arises from the unstable source current in the electrical device 3 and the operating clocks of various electrical components within the electrical device 3, thus mitigating the adverse influence of EMI on human bodies and interference with operation of other electrical components. In such examples, the primary winding and the secondary winding may be selected from the electrical conductive structure of this invention or general coil windings.

The above description is only for purpose of illustration. In other examples, the electrical device may be other inductive components, and the electrical conductive structure 30 for use as an EMI shield may further be disposed between other electrical components to provide EMI shielding function by means of the wire 33 grounded.

Since the electrical conductive structure of this invention reduces unnecessary volume occupation at the connecting location through spot-welding, the electrical device utilizing the electrical conductive structure as an inductive component and/or an EMI shielding layer is reduced in volume. In summary, the electrical conductive structure of this invention has a simple structural design and small volume, which complies with the current tendency towards lightweight, thin and miniaturized electrical devices. Meanwhile, by use of spot-welding instead of soldering, the manufacturing process is simplified, costs of the assembly materials are reduced, and consequently, market competitiveness of the product is enhanced.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. An electrical conductive structure, comprising:
a copper foil having a first surface and a second surface opposite the first surface;
an insulating layer overlaying the second surface and a portion of the first surface to define an exposed area on the first surface of the copper foil; and
at least one wire being spot-welded on the copper foil at the exposed area.

2. The electrical conductive structure as claimed in claim 1, wherein the at least one wire and the copper foil are substantially connected with each other by high temperature or high pressure melt.

3. The electrical conductive structure as claimed in claim 1, wherein the copper foil is formed with a longitudinal direction, and the at least one wire and the longitudinal direction are formed with an included angle which is less than 180°.

4. The electrical conductive structure as claimed in claim 1, wherein the copper foil is formed with a longitudinal direction, and the at least one wire is substantially parallel to the longitudinal direction.

5. The electrical conductive structure as claimed in claim 1, wherein the at least one wire is made of copper.

6. The electrical conductive structure as claimed in claim 1, wherein the at least one wire is a pin.

7. An electrical device, comprising the electrical conductive structure as claimed in claim 1.

8. The electrical device as claimed in claim 7, wherein the electrical device is an inductive component.

9. The electrical device as claimed in claim 7, wherein the electrical device is a transformer.

10. The electrical device as claimed in claim 9, wherein the electrical conductive structure is a primary winding.

11. The electrical device as claimed in claim 9, wherein the electrical conductive structure is a secondary winding.

12. The electrical device as claimed in claim 10, wherein the electrical conductive structure is a secondary winding.

13. The electrical device as claimed in claim 9, wherein the transformer comprises a primary winding and a secondary winding, and the electrical conductive structure is disposed between the primary winding and the secondary winding.

14. The electrical device as claimed in claim 13, wherein the electrical conductive structure is a shielding layer, and the at least one wire of the electrical conductive structure is grounded.
